(19) United States
(12) Patent Application Publication
(10) Pub. No.: US 2013/0207148 A1
(43) Pub. Date: Aug. 15, 2013

(54) RADIATION-EMITTING COMPONENT WITH A CONVERTER MATERIAL, WITH A THERMALLY CONDUCTIVE CONTACT AND METHOD FOR THE PRODUCTION THEREOF

(71) Applicants: Gertrud Kräuter, Regensburg (DE); Ralph Wirth, Lappersdorf (DE); Stefan Lange, Augsburg (DE); Frank Jermann, Königsbrunn (DE)

(72) Inventors: Gertrud Kräuter, Regensburg (DE); Ralph Wirth, Lappersdorf (DE); Stefan Lange, Augsburg (DE); Frank Jermann, Königsbrunn (DE)

(73) Assignees: OSRAM GmbH, München (DE); OSRAM Opto Semiconductors GmbH, Regensburg (DE)

(21) Appl. No.: 13/817,860

(22) PCT Filed: Aug. 22, 2011
(86) PCT No.: PCT/EP2011/064395

§ 371 Date: Apr. 29, 2013

(30) Foreign Application Priority Data
Aug. 20, 2010 (DE) 10 2010 034 913.5

(51) Int. Cl. H01L 33/58

(52) U.S. Cl. CPC H01L 33/58
USPC 257/98; 438/29; 257/79

(57) ABSTRACT

A radiation-emitting component includes:
a radiation source containing semiconductor materials which emits first radiation of a first wavelength when in operation;
a transparent body including a matrix material and an inorganic filler and arranged at least in part in the beam path of the first radiation; and
a converter material arranged at least in part in the beam path of the first radiation and which converts first radiation at least in part into second radiation of a second, longer wavelength.

### RELATED APPLICATIONS

This is a §371 of International Application No. PCT/EP2011/064395, with an inter-national filing date of Aug. 22, 2011 (WO 2012/022813 A1, published Feb. 23, 2012), which is based on German Patent Application 10 2010 034 913.5, filed Aug. 20, 2010, the subject matter of which is hereby incorporated by reference.

### TECHNICAL FIELD

This disclosure relates to a radiation-emitting component and to a method of producing the component.

### BACKGROUND

In radiation-emitting components with a light-emitting diode (LED) converter materials are often used. The converter material converts some of the incident radiation into radiation of a modified, longer wavelength, such that the converted radiation exhibits lower energy than the incident radiation (so-called “down-conversion”). The energy difference arises for the most part in the form of thermal energy such that the converter material heats up significantly. As a rule, efficiency of the converter material is temperature-dependent, in particular, efficiency of the converter material may be greatly reduced at high temperatures. The color appearance of the light output by the component may likewise depend on the temperature in the component.

Moreover, the converter materials may lend a colored appearance to a component in the off state (so-called “off-state appearance”). Converter materials excited, for example, by light in the blue spectral range absorb incident light, for example, daylight in the corresponding wavelength range even in the off state. Depending on the converter material, the material then has a yellowish, orange, reddish or green body color. In particular, in components in which a converter material is spatially remote from the radiation-emitting region, the radiation-outcoupling region of the component has an aesthetically disadvantageous colored appearance in the off state, which is brought about by the converter material.

For certain applications, high-efficiency radiation-emitting components with low radiation loss and high color constancy are desirable. Moreover, radiation-emitting components are desirable which have a radiation-outcoupling region which has a largely white or colorless appearance in the off state.

It could therefore be helpful to provide a radiation-emitting component with improved properties and a method of producing the radiation-emitting component.

### SUMMARY

We provide a radiation-emitting component including a radiation source containing semiconductor materials which emits first radiation of a first wavelength when in operation, a transparent body including a matrix material and an inorganic filler and arranged at least in part in a beam path of the first radiation, a converter material arranged at least in part in the beam path of the first radiation and which converts first radiation at least in part into second radiation of a second, longer wavelength, wherein the converter material is at least in part in thermally conductive contact with at least some of the filler of the transparent body.

We also provide a radiation-emitting component including a radiation source containing semiconductor materials which emits first radiation of a first wavelength when in operation, a transparent body including a matrix material and an inorganic filler and arranged at least in part in a beam path of the first radiation, wherein the inorganic filler has an average grain size of 5 to 20 μm, a converter material arranged at least in part in the beam path of the first radiation and which converts first radiation at least in part into second radiation of a second, longer wavelength, wherein the converter material is at least in part in thermally conductive contact with at least some of the filler of the transparent body.

### BRIEF DESCRIPTION OF THE DRAWINGS

FIG. 1 shows an example of our component.

FIG. 2 shows a further example of our component with a remote conversion element (remote phosphor conversion).

FIG. 3 shows a further example with a conversion element close to the radiation source (chip-level conversion).

FIG. 4 is a diagram showing the dependence of the thermal conductivity of a transparent body on filler content.

FIG. 5 is a diagram showing the reduce color point shift in our component compared to a conventional component.

FIG. 6 to FIG. 8 show further examples of components with a remote conversion element (remote phosphor conversion).

### DETAILED DESCRIPTION

We provide a radiation-emitting component comprising a radiation source containing semiconductor materials, which source emits first radiation of a first wavelength when in operation. The shorter term “component” is hereinafter also used for the radiation-emitting component.

The component may comprise a transparent body which includes a matrix material and an inorganic filler. The transparent body is arranged at least in part in the beam path of the first radiation. Just the term “filler” is also used hereinafter to denote the inorganic filler.

The component may comprise a converter material arranged at least in part in the beam path of the first radiation. The converter material converts at least some of the first radiation into second radiation of a second, longer wavelength, i.e., the first radiation has a higher energy than the second energy. The energy difference may arise in particular in the form of thermal energy. The thermal energy generated by conversion is hereinafter also known as “heat of conversion.”

The converter material may at least in part be in thermally conductive contact with at least some of the filler of the transparent body. The consequence of this is that at least some of the heat of conversion may be output to the filler or dissipated from the converter material via the filler. In this way, the converter material is advantageously protected from overheating and/or efficiency of the converter material is increased. Increased efficiency is distinguished in that a higher proportion of the first radiation is converted into the second radiation. As a result of improved heat dissipation, the component may, for example, also be operated with higher currents than conventional radiation-emitting components.

The radiation source containing semiconductor materials is, for example, a light-emitting diode (LED) or laser diode. The radiation source may also take the form of a plurality of light-emitting diodes and/or laser diodes, which emit at the same or at different first wavelengths. The spectrum of the first radiation is known as the first wavelength. The first wavelength may be in the visible range of the spectrum (420 to 780 nm wavelength), in particular in the blue spectral range, in the UV range (<420 nm) and in the IR range (>780 nm). The first radiation may in particular comprise a wavelength maximum of below 600 nm. The semiconductor materials are not restricted, provided they at least partially are capable of exhibiting electroluminescence. Compounds of elements are, for example, used which may be selected from indium, gallium, aluminium, nitrogen, phosphorus, arsenic, oxygen, silicon, carbon or combinations, for example, indium gallium nitride (InGaN) or indium gallium aluminium phosphide (InGaAlP). Other elements or additives may also be used.

The choice of converter materials is not restricted. It is possible to use ceramics doped with rare earth metals and/or transition metals as the luminescent material as described, for example, in WO 98/12757, the subject matter of which is hereby incorporated by reference. The converter material may comprise or consist of a luminescent material or a combination of different luminescent materials. By using the converter materials, the color appearance of the emitted radiation is modified. The component may, for example, emit radiation with a white color appearance or another color appearance.

The refractive index of the matrix material and the refractive index of the inorganic filler may vary with the temperature. The temperature-dependent profile of the refractive index is generally different for the matrix material and for the filler.

Refractive index is determined using a refractometer, with which the temperature may be adjusted and/or regulated. Room temperature is assumed to be a temperature of 20° C. The refractive indices reported below have been determined for the wavelength of sodium D line at 589 nm. A refractive index at room temperature in this application thus corresponds to “n_{D}²⁰.” The accuracy of a reported refractive index amounts to at least 0.001 and in particular at least 0.0005.

The matrix material and the filler may be selected such that at room temperature the matrix material has a 0.01 to 0.07, in particular 0.01 to 0.05, higher refractive index than the filler. Moreover, the matrix material has a higher thermo-optic coefficient than the filler such that on heating to operating temperature the difference between the refractive indices of the matrix material and of the filler decreases. At operating temperature the difference in the refractive indices is 0.015.

The thermo-optic coefficient dn/dT indicates how the refractive index n changes as the temperature T changes, i.e., it describes the change in refractive index per ° C.

For example, the profile of the refractive index relative to temperature in the relevant temperature range both for the matrix material and the filler may be described approximately by a straight line. These straight lines may have a different gradient, wherein a point of intersection of the straight lines typically lies in the range of the operating temperature. This temperature may be up to 20° C., in particular up to 10° C. and often up to 5° C. higher or lower than the operating temperature or it may correspond thereto. The corresponding thermo-optic coefficient then indicates the gradient of such a straight line.

The thermo-optic coefficient may be determined for a material by multiple measurements of the refractive index at different temperatures.

The matrix material at room temperature may have a thermo-optic coefficient of −5*10⁻⁵ to −5*10⁻³ 1/° C., in particular of −1*10⁻⁴ to −1*10⁻³ 1/° C.

The thermo-optic coefficient of the filler is generally lower than the thermo-optic coefficient of the matrix material. At room temperature, the filler has a thermo-optic coefficient of up to −5*10⁻⁵ 1/° C., for example, −5*10⁻⁷ to −5*10⁻⁵ 1/° C. This means that in the relevant temperature range the refractive index of the filler for the most part varies less than the refractive index of the matrix material.

The refractive index of the filler may be regarded as approximately constant compared to the refractive index of the matrix material at least in the relevant temperature range. The relevant temperature range comprises the temperatures between room temperature and operating temperature.

When the component is started up, the temperature in the component for the most part corresponds to ambient temperature, for example, room temperature. After start-up of the component the temperature in the component initially rises sharply and usually reaches a comparatively constant value after a certain time (at constant current and constant ambient temperature). As a rule this occurs within up to 30 minutes. Operating temperature is understood to be a temperature in the component which is present at a point 45 minutes after switch-on in the case of uninterrupted operation of the component.

A temperature corresponding to the value of the operating temperature may be reached in the component at an earlier point and remain constant. This temperature is hereinafter likewise described as “operating temperature.” The operating temperature counts as constant if the temperature during ongoing operation (at constant current and constant ambient temperature) fluctuates by less than 5° C., in particular less than 3° C. and often less than 1° C.

The operating temperature of the component may be up to 200° C. The operating temperature is in particular 70° C. to 150° C., often 80° C. to 120° C., for example, 110° C.

The transparent body is preferably transparent at operating temperature in the wavelength ranges of the first radiation and the second radiation. Being “transparent” at a wavelength means that transmission is ≧70%, in particular ≧80%, for example 86% at the corresponding wavelength.

The matrix material may have a refractive index which at room temperature is 0.01 to 0.04 and in particular 0.015 to 0.035 higher than the refractive index of the filler.

At operating temperature the difference between the refractive indices of the matrix material and of the filler is ≦0.01, in particular ≦0.0075, for example, ≦0.005.

At operating temperature the transparent body exhibits a transmission at a wavelength of 600 nm of ≧90%, in particular ≧95% and often ≧98% auf. This does not take account of any Fresnel losses which occur on entry of the radiation into the transparent body and exit of the radiation therefrom (in each case approx. 4%).

At operating temperature the refractive index of the matrix material may be higher or lower than or the same as the refractive index of the filler. Through the slight or completely absent difference in the refractive indices at operating temperature, radiation generated in the component is virtually not scattered and/or absorbed at all by the transparent body, so reducing or preventing radiation losses. In contrast, when the component is switched on a higher proportion of the emitted radiation is scattered and/or absorbed compared with operating temperature since the difference in the refractive indices of the matrix material and the filler is greater than at operating temperature.

Because of the difference in the refractive indices of the filler and the matrix material, the transparent body scatters light comparatively strongly at room temperature. The transparent body may then be opaque. This effect is also observed at temperatures of close to or below room temperature. The transparent body may therefore scatter incident light comparatively strongly even when the component is switched off such that the body color of the converter material can barely be perceived from outside, i.e., by an observer, or ideally can no longer be perceived at all. Advantageously the radiation-outcoupling region of the component therefore has a white or colorless appearance (off-state appearance) when switched off. The transparent body may thus act as a diffuser when switched off. These advantages are achieved in particular when relatively large quantities of converter material are spatially remote from the radiation source.

As already explained above, the difference in the refractive indices of filler and matrix falls on heating to operating temperature. Advantageously, the transparent body may thus act as a temperature-dependent diffuser which absorbs light strongly in the off state, but absorbs barely any light at operating temperature. When in operation, the component thus exhibits distinctly higher efficiency than conventional components in which the body color of the converter material in the off state is concealed by, for example, opal glass or a roughened coating of glass or plastics which absorb a considerable proportion of the radiation generated even when the component is in operation.

The emission pattern of the component may be improved by a small difference in the refractive indices of the matrix material and the filler, for example, of 0.01. In this way, for example, angle dependence of the emission may be reduced or color uniformity improved.

The inorganic filler may comprise or consist of a metal fluoride, for example, an alkaline earth fluoride. The metal fluoride may be selected, for example, from magnesium fluoride (MgF₂), lithium fluoride (LiF), calcium fluoride (CaF₂), barium fluoride (BaF₂) or a combination thereof. The metal fluoride may typically exhibit a refractive index at room temperature of 1.37 to 1.50, for example, 1.39 for MgF₂, 1.40 for LiF, 1.43 for CaF₂ and 1.46 for BaF₂. The filler may be monocrystalline and/or polycrystalline.

The inorganic filler may comprise or consist of a glass, quartz, silica gel, SiO₂ particles, in particular spherical SiO₂ particles, a borosilicate glass or a combination thereof. For example, SiO₂ particles have a refractive index at room temperature of 1.46, glass one of 1.45 to 2.14, a borosilicate glass one of 1.50 to 1.55.

The filler may comprise or consist of a silicate, a ceramic or an aluminium oxide, for example, corundum.

The matrix material may comprise or consist of a silicone, an epoxy resin, an acrylic resin, a polyurethane, a polycarbonate or a combination thereof. The matrix material may also comprise or consist of a mixture of different plastics and/or silicones. The matrix material may in particular comprise or consist of a silicone, a methyl substituted silicone, for example, poly(dimethylsiloxane) and/or polymethylphenylsiloxane, a cyclohexyl-substituted silicone, for example, poly(dicyclohexyl)siloxane, or a combination thereof.

For example, an epoxy resin or an acrylic resin may exhibit a refractive index at room temperature of 1.46 to 1.60, in particular 1.48 to 1.53. As a rule, a polycarbonate exhibits a higher refractive index, for example, 1.55 to 1.65, in particular 1.58 to 1.60. A silicone exhibits a refractive index of 1.40 to 1.54.

It is particularly advantageous for the refractive index of the matrix material to be adjusted such that it is higher at room temperature than the refractive index of the filler since the thermo-optic coefficient of the matrix material is often higher than the thermo-optic coefficient of the filler. Thus, the refractive index of the matrix material falls more rapidly than the refractive index of the filler as the temperature rises when the component is in operation.

Selection of the matrix material may depend on the inorganic filler and thereby fulfill the above criterion of the matrix material exhibiting a higher refractive index at room temperature and a higher thermo-optic coefficient than the filler. For a filler of borosilicate glass, for example, a matrix material comprising or consisting of an epoxy resin, a polycarbonate or a combination thereof may be suitable. For a filler of glass or of SiO₂ particles, for example, a matrix material comprising or consisting of a silicone or an acrylic resin may be suitable.

For an inorganic filler comprising or consisting of a metal fluoride, a silicone or a combination of various silicones may be used as matrix material. A combination of at least one silicone with at least one other plastics material may also be used.

The refractive index of a silicone depends in particular on the organic substituents R¹, R² and R³ on the silicon atom and on the degree of branching of the silicone. Terminal groups of the silicone may be described as R¹R²R³SiO_{1/2}, linear groups as R¹R²SiO_{2/2} and branching groups as RiSiO_{3/2}. R¹ and/or R² and/or R³ may be selected independently on each silicon atom. R¹, R² and R³ are in this case selected from a variety of organic substituents with different numbers of carbon atoms. The organic substituents may be at any desired ratio to one another in a silicone. As a rule, a substituent comprises 1 to 12, in particular 1 to 8, carbon atoms. R¹, R² and R³ are selected, for example, from methyl, ethyl, cyclohexyl or phenyl, in particular methyl and phenyl.

Organic substituents with many carbon atoms generally increase the refractive index, while smaller substituents result in a lower refractive index. A silicone rich in methyl groups may, for example, have a low refractive index, for example, of 1.40 to 1.44. A silicone which is, for example, rich in phenyl groups or cyclohexyl groups may, on the other hand, exhibit a higher refractive index.

Likewise, with other matrix materials than silicones the refractive indices may be adjusted by selection of substituents and/or by hybrid materials, for example, silicone epoxy.

For a filler of SiO₂ particles with a refractive index at room temperature of 1.46, for example, a polymethylphenylsiloxane with a refractive index of between 1.48 and 1.50, for example, 1.49, may be used. A cyclohexyl-substituted silicone with a refractive index of 1.47 to 1.49, for example, 1.48, may likewise be suitable for SiO₂ particles. Typically, a silicone rich in methyl groups is suitable as a filler of magnesium fluoride or lithium fluoride. Poly(dimethyl-siloxane) may, for example, be used, which is advantageous since it is particularly inexpensive.

It is additionally possible to adjust the refractive index of the matrix material by mixing different matrix materials. For example, the refractive index of a silicone matrix may be adjusted by mixing various silicones having different refractive indices. In this way, the matrix material may comprise or consist of a polymer mixture of silicones with different organic substituents. It is however also possible for a silicone copolymer to be produced from various monomers comprising different organic substituents, and thus for the refractive index of the matrix material to be adapted accordingly. A mixture of various silicone copolymers with various refractive indices may also be used to adjust the refractive index of the matrix material.

The transparent body has a filler content of up to 80 wt. % (wt. %=percent by weight). The transparent body contains in particular 25 to 70 wt. % and often 30 to 60 wt. % of filler, for example, 50 wt. % of filler. This in particular makes possible high thermal conductivity of the transparent body.

In some applications, for example, if the transparent body is intended to serve as a temperature-dependent diffuser, to conceal the body color of the converter material when the component is switched off, it is also possible to use a lower filler content. The filler content may thus amount to 5 to 50 wt. %. The filler content generally amounts to 10 to 40 wt. %, in particular 15 to 30 wt. %. In this region a very good scattering action of the transparent body is achieved at room temperature. At a very high filler content, the scattering action could fall somewhat at room temperature.

The filler may form continuous filler paths in the transparent body. These filler paths are also known as “percolation” paths and generally form randomly. They may extend over the entire transparent body. This typically occurs from a filler content of 28 to 35 vol. %, generally 30 to 32 vol. %, i.e., the “percolation threshold” (vol. %=percent by volume). Advantageously, the thermal conductivity of the transparent body increases with filler paths.

By purposeful adaptation of the refractive indices of the matrix material to the filler, radiation losses or brightness losses in the transparent body are reduced or prevented even at a high filler content of ≧30 vol. %, in particular of ≧40 vol. %.

Moreover, permeability of the transparent body compared with a conventional matrix of a pure polymer material, in particular of a silicone, is reduced by the filler, in particular at a high filler content. The transparent body in particular exhibits a lower permeability to moisture and/or pollutant gases. In this way, the radiation source is protected in particular, whereby the service life of the component is increased.

In addition, the mechanical properties of the transparent body may also be improved by the filler. For example, the coefficient of thermal expansion of the transparent body is lower than that of a conventional matrix of a pure polymer material. In this way, the service life of the component may be increased since, for example, the risk of cracks in the transparent body is reduced.

The filler may have an average grain size of up to 100 μm. The average grain size is as a rule between 100 nm and 20 μm, in particular is 5 to 20 μm. For certain applications smaller particles may also be used at least in part, for example, with an average diameter 1 μm, preferably 200 to 800 nm and in particular 200 to 500 nm, since with these the radiation may be strongly scattered which may lead to improved color uniformity. Particles with an average diameter of 100 nm to 1 μm are particularly suitable to bring about strong scattering of the transparent bodies in the off state and reduced scattering at operating temperature, i.e., to provide a temperature-dependent diffuser. The parameter used for the grain size is generally the diameter. The particle diameter is determined using a screening method.

The filler may, for example, consist of spherical or virtually spherical particles such that the diameter corresponds approximately to the grain size. The filler may also exhibit other particle shapes, for example, angular, elongate or amorphous particle shapes. With such particles the averaged diameter is used as a measure of the grain size.

The filler may exhibit a grain size of ≧2 μm and in particular of ≧4 μm. Smaller particles may be separated out using a screening method. Since particles with a grain size of <2 μm and in particular of <1 μm may scatter light very strongly at their surface, the radiation losses in the transparent body are reduced and efficiency of the component is increased overall. Such an example may in particular be used in a component in which the converter material is arranged directly on or close to the radiation source since in such components the colored appearance of the converter material is less obvious to the observer.

The filler may have a higher thermal conductivity than the matrix material. The thermal conductivity of the pure matrix material typically amounts to 0.1 to 0.2 W/mK. For example, a silicone exhibits a thermal conductivity of 0.12 to 0.18, for example, 0.15 W/mK. In contrast, the inorganic filler exhibits a thermal conductivity of ≧1.0 W/mK, in particular of ≧10 W/mK. Spherical SiO₂ particles exhibit a thermal conductivity of 1.38 W/mK, for example. Advantageously, metal fluorides as a rule exhibit a markedly higher thermal conductivity, for example, MgF₂ exhibits one of 14 W/mK, LiF one of 11 W/mK, CaF₂ one of 10 W/mK and BaF₂ one of 12 W/mK.

The transparent body may exhibit a thermal conductivity of ≧0.25 W/mK and in particular ≧0.30 W/mK auf. The thermal conductivity may, in particular with metal fluorides, be ≧2 W/mK and often ≧5 W/mK. Combining the filler with the matrix material advantageously gives the transparent body of our component a higher thermal conductivity than a conventional matrix of a pure polymer material. Heat transfer through the transparent body may in this case proceed in particular via filler paths which have formed. Even if the filler content is below the percolation threshold, the thermal conductivity of the transparent body is higher than that of a pure matrix material.

The component may comprise a housing with a recess. The housing may, for example, comprise or consist of a plastics material, a ceramic or a combination thereof. The housing may also comprise radiation-reflecting materials in particular at the side walls of the recess. The radiation source, the transparent body and the converter material may be arranged in the recess. The side walls of the recess may in particular be at an angle to the bottom of the recess such that the radiation may be reflected.

The radiation source may be arranged on the bottom of the recess. The transparent body at least partly fills the recess and may assume the function of a potting compound or of a scattering body.

The component may comprise a bond pad and a bonding wire the latter of which connects the radiation source conductively with the bond pad. The bond pad may likewise be arranged in the recess. The bond pad and the radiation source are connected with electrically conductive connectors which may extend out of the housing. The electrically conductive connectors may be at least part of a lead frame.

The radiation source may be in thermally conductive contact with a heat sink, for example, a part of the lead frame.

At least parts of the radiation source, the electrical connectors, and/or the lead frame may exhibit high thermal conductivity and may serve to dissipate heat out of the component and in particular from the radiation source. In the process, heat may also be dissipated via the transparent body or via the filler paths in the transparent body.

The converter material may connect at least in part thermally conductively via the transparent body or via the filler paths in the transparent body to the radiation source and/or to the electrically conductive connectors and/or to the lead frame. In this way, the heat of conversion may be dissipated from the converter material and then conveyed further out of the component. In this way, heat dissipation in the component is further improved.

Converter materials and in particular converter materials which emit in the red range of the spectrum and are excited with shortwave radiation, for example, in the blue range of the spectrum, produce a lot of heat of conversion and run the risk of overheating. Moreover, their efficiency may fall significantly on heating to operating temperature, for example, by up to 50%. This may cause the color appearance of the radiation emitted by the component to change on heating. The improved thermal conductivity of the transparent body compared to a conventional matrix of a pure polymer material without a heat-conducting filler increases the efficiency of the converter material. The temperature at the converter material, which may be in thermally conductive contact with the filler in the transparent body, may be lowered by up to 40% compared to a conventional component of similar construction without a filler. For example, with 40 to 50 wt. % of SiO₂ particles in the transparent body, the temperature at the converter material may be lowered by 15 to 30%, in particular 22 to 30% and often 25 to 30%. With a filler of metal fluoride the temperature may be reduced by 20 to 40%, in particular by 30 to 40% and often by 35 to 40% with a filler content of 40 to 60 wt. %. Thus, overheating of the converter material is also prevented or at least the likelihood thereof is reduced. In addition, the radiation emitted by the component typically has a constant color appearance.

The fall in efficiency of the converter material on heating from room temperature to operating temperature may, in some examples of our components, be compensated at least in part by the reduction in scatter and/or absorption of radiation in the transparent body, if the components comprise a matrix material whose refractive index, as described above, is adapted to the refractive index of the filler such that the difference in the refractive indices of the matrix material and the filler reduces at operating temperature. Advantageously, a constant color appearance is obtained for the radiation emitted by the component.

With a converter material, the wavelength of the converted radiation may additionally vary with the temperature, so resulting in displacement of the color point of the converted radiation in the CIE diagram. This temperature-dependent displacement of the color appearance of the converted radiation is also known as a color point shift. Such a color point shift is generally particularly pronounced in the case of a large emission angle θ(θ=theta) to the main emission direction (θ=0°) of the radiation source. In our component, such a color point shift is reduced compared to conventional radiation-emitting components since the heat of conversion is dissipated efficiently from the converter material via the transparent body or via the filler paths in the transparent body. This advantageously results in greater color constancy.

The transparent body may be combined with particles which comprise or consist of a converter material. These particles may be distributed uniformly in the transparent body. The transparent body may, for example, form a potting compound together with the particles which wholly or partially fills the recess in the component. The transparent body may, for example, also be produced as a layer arranged in the recess or in the region of the recess mouth. The converter material contained in the particles is then at least partially in thermally conductive contact with the filler.

The particles may be in thermally conductive contact with at least one filler path. A filler path may be interrupted by such a particle and nonetheless have its normal thermal conductivity. Such an interrupted filler path may also take the form of two separate filler paths, which extend from the particle out of the transparent body. For example, the particles may also form continuous paths or percolation paths with the filler.

The particles which may comprise or consist of the converter material generally exhibit a size of up to 60 μm, in particular of 5 to 40 μm and often of 10 to 30 μm.

The component may comprise a conversion element. The conversion element may comprise the converter material, but it may also contain further materials such as, for example, a binder. The conversion element may take the form of a discrete element, i.e., the conversion element may be unambiguously distinguished from its surrounding environment or other parts of the component by optical methods, for example, by light microscopy. The conversion element may be self-supporting such that it may be handled with forceps or another tool.

The transparent body may form a conversion element with particles containing or consisting of the converter material. The conversion element may comprise further materials, for example, a binder. The conversion element may be discrete and/or self-supporting. Through the thermally conductive contact of the converter material with the filler, the heat of conversion is dissipated at least in part to the edge of the conversion element.

The conversion element which may contain the converter material and may comprise the transparent body is remote from the radiation source. An example of a remote conversion element is “remote phosphor conversion.” Such a conversion element may in certain applications also be combined with a second conversion element arranged close to or directly on a radiation source (“chip-level conversion”).

The conversion element may be spaced from the radiation source by a potting compound. This potting compound may be a conventional potting compound of a polymer material. In particular, the potting compound may comprise or consist of a transparent body. The heat of conversion is dissipated from the conversion element at least in part via the transparent body or via the filler paths. In particular, the heat is in this way dissipated from the conversion element at least in part further on to the radiation source and/or to the electrically conductive connectors and/or to the lead frame. The component may comprise a conversion element which comprises a transparent body, and also a potting compound which contains or consists of a transparent body.

The distance between the conversion element and the radiation source may be ≦200 μm, and in particular ≦50 μm such that conversion proceeds close to the radiation source (chip-level conversion). The conversion element here preferably takes the form of a wafer or a chip. Other forms may likewise be used. The conversion element is here, for example, bonded to the radiation source by a potting compound. The component may comprise a further potting compound which, for example, wholly or partially fills the remaining recess. At least one of the potting compounds comprises a transparent body or consists of a transparent body. The two potting compounds may also be identical.

The conversion element may be at a distance of >200 μm, in particular of ≧750 μm and often of ≧900 μm from the radiation source such that conversion takes place at a large distance from the radiation source (remote phosphor conversion). The conversion element may be spaced from the radiation source via a potting compound. The potting compound may here comprise or consist of a silicone, an epoxy resin, an acrylic resin, a polyurethane, a polycarbonate or a combination thereof. The potting compound may, however, also comprise or consist of a transparent body. The conversion element may be spaced from the radiation source via a cavity. Such a cavity may be filled with air, an inert gas or a gas mixture. Such an example is advantageously inexpensive to produce. The conversion element may, as already described, likewise comprise a transparent body.

The conversion element may be arranged in the mouth of the recess. The conversion element may here, for example, take the form of a flat or curved layer. In this case, the conversion element may have an average layer thickness of 10 to 2000 μm. The layer thickness may amount to 50 to 1000 μm, in particular 50 to 500 μm.

The conversion element may enclose a curved hollow body. This is in particular understood to mean that the conversion element, together with at least one further part of the component, encloses a hollow body. This part may, for example, be a carrier on which the radiation source is arranged or a housing, in the recess in which the radiation source is arranged. The conversion element may here take the form of a layer exhibiting an average layer thickness as described in the previous paragraph. The hollow body may, for example, take the form of a hollow hemisphere or of a hollow portion of a sphere. The radiation source is preferably arranged in the hollow body and may be remote from the conversion element, for example >750 μm (remote phosphor conversion). The resultant hollow body may be partially or completely filled, for example, with air, an inert gas, or also a potting compound or a transparent body. The conversion element may likewise contain a transparent body. Thus, the body color of the converter material is advantageously barely or not at all perceptible to the observer from outside at room temperature. Rather, the conversion element takes on an aesthetically appealing white or colorless appearance.

The component may comprise a conversion element which contains the converter material and is remote from the radiation source, wherein the transparent body is arranged on the side of the conversion element facing away from the radiation source. The transparent body may be produced directly on the conversion element such that the filler is also at least in part in thermally conductive contact with the converter material. Alternatively, a thermally conductive, transparent layer, for example, of glass, silicone or plastics, may also be produced therebetween. Advantageously, the transparent body surrounds the conversion element such that the latter is externally enclosed and thus at room temperature appears barely colored but instead, largely white or colorless to the observer.

The transparent body arranged on the conversion element may have an average layer thickness of 50 to 500 μm. With these low layer thicknesses only very little radiation is absorbed in operation.

Doping with the converter materials and/or the selection of the converter materials, for example, in a conversion element, may be adapted such that at room temperature precisely the required temperature is achieved by the heat of conversion, at which temperature the transparent body exhibits its greatest transparency. “Precisely” is here understood to mean a deviation of ≦3° C., in particular of ≦2° C. Deviation may even be ≦1° C. “Greatest transparency” is here understood to mean a range including maximum transparency. In this range transparency amounts to ≧95%, in particular ≧97% of maximum transparency. Transparency may even be ≧99% of maximum transparency.

An enveloping layer may be produced on the conversion element, at least in part. This layer may in particular consist of glass or a transparent plastics material and may also form an outer wall of the component, for example, the envelope of a lamp. A transparent body may be arranged between conversion element and enveloping layer.

The conversion element or a potting compound may form a lens. The lens may, for example, fill the mouth of the recess or be arranged therein. The lens may comprise a cavity which may be filled with a further material. This material may, for example, comprise or consist of a gas, a gas mixture, a plastics or polymer material, a glass or other material or a combination of multiple materials.

In general, in a component with “chip-level conversion” the heat of conversion is dissipated better from the converter material since the distance, for example, from the radiation source and/or from the electrically conductive connectors and/or from the lead frame is short. However, in a component with “remote phosphor conversion” the converter material may, depending on construction, exhibit greater efficiency than an identical converter material with “chip-level conversion.” This applies to components in which particles containing or consisting of the converter material are mixed with a potting compound. Through the greater distance from the radiation source, the heat of conversion may often only be inadequately dissipated from the converter material. In one example of our component, heat transfer may proceed at least in part via the transparent body or via the filler paths in the transparent body. In this way, in particular in components with “remote phosphor conversion” or with a potting compound with a transpar-ent body mixed with particles containing or consisting of the converter material, the efficiency of the converter material increases and overheating of the converter material is prevented.

General advantages of components with “remote phosphor conversion” over other conversion methods are, for example, that the converter material is exposed to a lower radiation load. In this way, converter materials may also be used which are unsuitable to conversion close to the radiation source (“chip-level conversion”).

Moreover, a component with “remote phosphor conversion” has a better emission pattern, since more diffuse emission can be achieved without the observer experiencing glare, as may arise with conversion close to the radiation source. In addition, the radiation source and housing are exposed to less thermal stress, so increasing the service life of the component.

In a component with “remote phosphor conversion”, in comparison with a component with conversion close to the radiation source, efficiency is increased since the housing generally exhibits greater reflectivity for the radiation of the first and second wavelengths than the radiation source. The housing may, for example, be provided with a reflector, such that its reflectivity is >90%, while the reflectivity of the radiation source is often <90%.

The transparent body may also be used in incandescent lamps, tungsten-halogen lamps, in particular tungsten-halogen lamps with a large base such as, for example, an E27 base, or indeed also compact fluorescent lamps. In these components the body color of a converter material or the filaments or connectors may be concealed at room temperature by the transparent body, which takes the form of a temperature-dependent diffuser. The transparent body may, for example, be arranged on or in the glass envelope of such a lamp. At operating temperature the emitted radiation is then not absorbed or is absorbed only slightly, since the transparent body is then transparent.

The refractive index of the matrix material at room temperature may be equal to or up to 0.04 less than the refractive index of the filler. On heating to operating temperature this difference may increase, for example, to 0.04 to 0.08, whereby the radiation is more strongly scattered, which may be desirable to improve color uniformity.

A method of producing the radiation-emitting component is also provided, the method comprising the following method steps:
(a) providing a radiation source containing semiconductor materials, which emits first radiation of a first wavelength when in operation;
(b) producing a transparent body, which comprises a matrix material and an inorganic filler;
(c) arranging the transparent body in the beam path of the first radiation; and
(d) arranging converter material in the beam path of the first radiation, such that at least some of the converter material is in thermally conductive contact with at least some of the filler of the transparent body.

In method step (b) the matrix material may be adapted to the filler such that at room temperature the matrix material has a refractive index 0.01 to 0.07, in particular 0.01 to 0.05, higher than the filler. Moreover, the matrix material may be selected such that at the operating temperature of the component the difference in the refractive indices of the matrix material and of the filler is ≦0.015. This may take place in particular with consideration of the different thermo-optic coefficients of the matrix material and of the filler. In particular, the refractive index of the matrix material at room temperature is 0.01 to 0.04, often 0.015 to 0.035 higher than that of the filler. In particular, the difference in the refractive indices at operating temperature is ≦0.01, often ≦0.075, for example, ≦0.005.

In method step (b) at least one silicone with organic substituents on the silicon atoms may be used as a matrix material. At room temperature, the refractive index of the silicone may be adjusted in a range from 1.40 to 1.54 by varying the organic substituents and their ratio, the substituents exhibiting different numbers of carbon atoms, as described above.

The refractive index of the matrix material may at least in part be adjusted by combining different plastics and/or different silicones.

In method step (b) the following sub-steps may be performed:
1. determining the refractive index of the filler at room temperature and/or operating temperature of the component.
2. adjusting the refractive index of the matrix material while taking account of the thermo-optic coefficient of the matrix material such that there is a difference of 0.015 in the refractive indices of the matrix material and of the filler at operating temperature of the component. In particular, the difference in the refractive indices at operating temperature is ≦0.01, often ≦0.0075, for example, ≦0.005.
3. producing the transparent body.
   Under step 2 it is also initially possible to determine the refractive indices of a plurality of different plastics and/or different silicones.

Steps (b) and (c) may be performed together. The matrix material may be mixed with the filler at room temperature or heated somewhat for the purpose. Mixing generally proceeds at a temperature of ≦70° C., in particular ≦60° C. Further materials may be added. This mixture may, for example, be used to fill a recess in the component where it forms the transparent body in the beam path of the first radiation. To cure the transparent body, it may be heated to higher temperatures.

Steps (b), (c) and (d) are combined. For example, the matrix material at room temperature or as described above may be mixed at ≦70° C., in particular ≦60° C., with the filler and particles which the converter material comprises or of which it consists. Further materials may be added. This mixture may, for example, be used to fill the recess in the component where it forms a transparent body mixed with the particles in the beam path of the first radiation. For curing purposes, heating may optionally be performed. In this way, a conversion element may also be formed.

In further method steps for which no specific order is specified, further constituents of a component may be provided or arranged. Further method steps may also be performed together with method steps as already stated.

Our components and methods are explained below with reference to the drawings in particular by way of examples. The same reference numerals in each case indicate the same elements in the individual figures. The relationships between the elements are not shown to scale, however, but rather individual elements may be shown on an enlarged scale and/or schematically to assist in understanding.

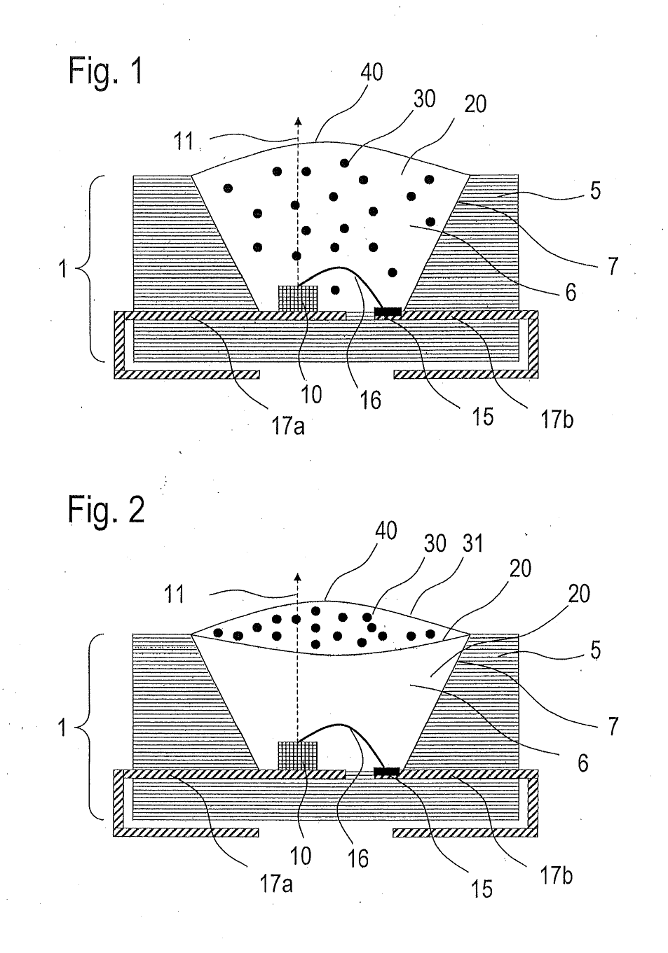

FIG. 1 shows a schematic cross-section of a radiation-emitting component 1. The component 1 has a housing 5 with a recess 6 in which a semiconductor chip, an LED, is arranged as radiation source 10 on the bottom of the recess 6. Arranged on the bottom of the recess 6 is a bond pad 15 which connects conductively via a bonding wire 16 to the semiconductor chip 10. The semiconductor chip 10 and the bond pad 15 connect with electrically conductive connectors 17a, 17b, which may extend out of the housing 5 of the component 1 and are intended for electrical contacting. The electrically conductive connectors 17a, 17b may be part of the lead frame. The side walls 7 of the recess 6 may comprise a reflective material such as, for example, TiO₂ or a metal coating.

The recess 6 is filled with a potting compound. The potting compound consists of the transparent body 20 and of particles which contain or consist of at least one converter material 30. The potting compound may contain 4 to 12 wt. %, in particular 5 to 10 wt. % of converter material 30. The potting compound may also contain further materials. The transparent body 20 and the converter material 30 are thus arranged at least in part in the beam path 11, here shown by a dashed arrow. For clarity's sake in FIG. 1, the beam path 11 is indicated as being the main emission direction. The radiation may also be emitted at an angle θ to the main emission direc-tion. In this example, the potting compound may form a lens 40 at the top end of the recess 6.

The filler in the transparent body 20 is not shown for the sake of clarity. The filler may form filler paths which connect the converter material 30 at least in part thermally conductively to the radiation source 10 and/or the electrically conductive connectors 17a, 17b and/or the lead frame. The heat of conversion is dissipated from the converter material 30 in this way when in operation. The transparent body 20 contains, for example, a cyclohexyl-substituted silicone as a matrix material with a refractive index of 1.47 to 1.49, for example, 1.48, and 40 to 50 wt. % of SiO₂ particles as a filler. At room temperature radiation is scattered by the transparent body, whereas at 100° C. the transparent body is transparent, with a transmission of ≧95%, in particular ≧98%, at a wavelength of 600 nm. The temperature at the converter material is lower by 15 to 30% compared to a conventional component with a potting compound of silicone, the efficiency of the converter material thereby being increased.

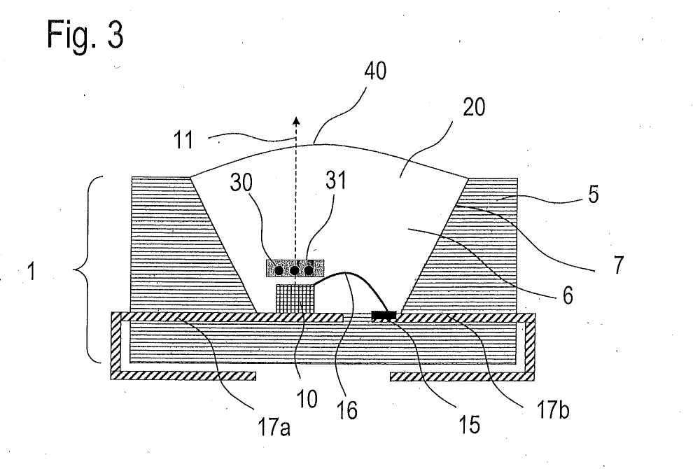

FIG. 2 shows a schematic cross-section through a component 1 according to a further example. In the region of the mouth of the recess 6 there extends a conversion element 31 which contains at least one converter material 30. The content of converter material 30 in the conversion element 31 may amount, for example, to 10 to 30 wt. %, in particular 15 to 25 wt. %. The conversion element 31 may also contain a transparent body 20. The distance from the radiation source 10 is here >200 μm, in particular ≧750 μm (remote phosphor conversion). In this example, the conversion element 31 forms a lens 40. The conversion element 31 is spaced from the radiation source 10 by a potting compound which may consist of a transparent body 20. In particular, both the conversion element 31 and the potting compound may contain a transparent body or the latter may consist thereof.

In operation, the heat of conversion is dissipated from the converter material 30 via a transparent body 20 or via the filler paths in the transparent body 20 and the efficiency of the converter material 30 is thereby increased.

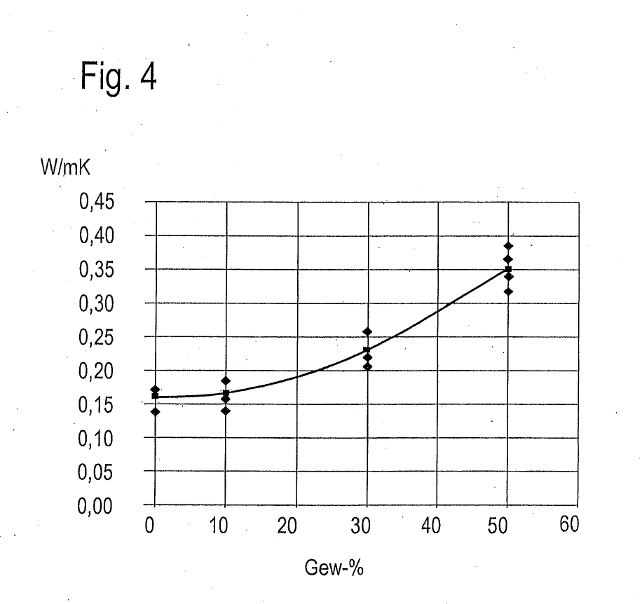

FIG. 3 shows a schematic cross-section of a component 1 according to a further exam-ple. A conversion element 31 with the converter material 30 is bonded to the semiconductor chip 10 via a transparent body 20 which may here assume the function of an adhesive. The conversion element 31 may contain, for example, 20 to 70 wt. %, in particular 30 to 60 wt. %, of converter material 30. The distance from the radiation source 10 is ≦200 μm, in particular ≦50 μm (chip-level conversion). The conversion element 31 may contain a transparent body (not shown). The conversion element 31 takes the form of a wafer, but other forms may also be used for the conversion element 31. The recess 6 is filled with a potting compound which may consist of a transparent body 20. In this example, the potting compound may form a lens 40.

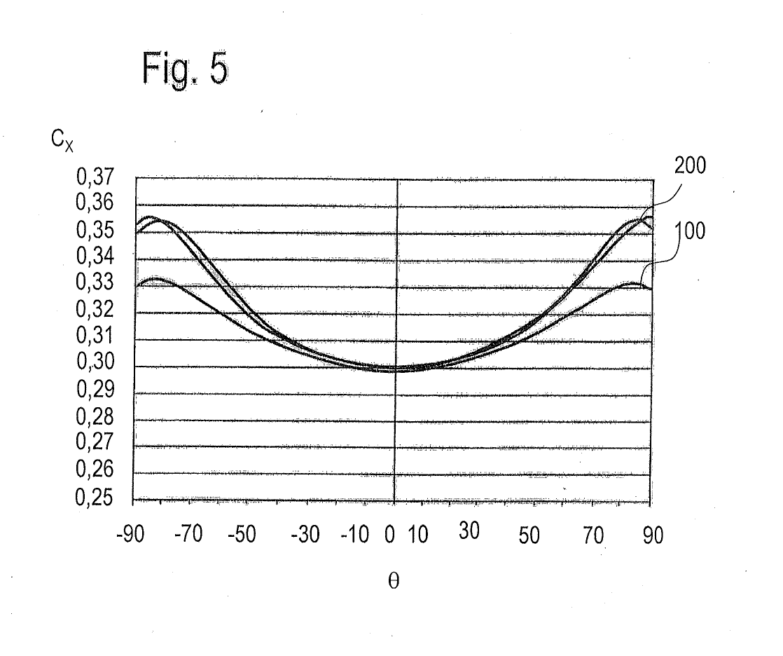

FIG. 4 shows the dependence of the thermal conductivity in W/mK (y axis) on the filler content in wt. % (x axis) of a potting compound which is a mixture of a transparent body 20 consisting of poly(dimethylsiloxane) as matrix material and a variable percentage of spherical SiO₂ particles as filler, with 7 wt. % of particles of a cerium-doped yttrium aluminium garnet (YAG:Ce). Without filler particles, the potting compound has a thermal conductivity of approx 0.15 W/mK. With 30 wt. % of SiO₂ particles a thermal conductivity of approx 0.23 W/mK is observed in the potting compound and with 50 wt. % of SiO₂ particles a thermal conductivity of approx 0.35 W/mK.

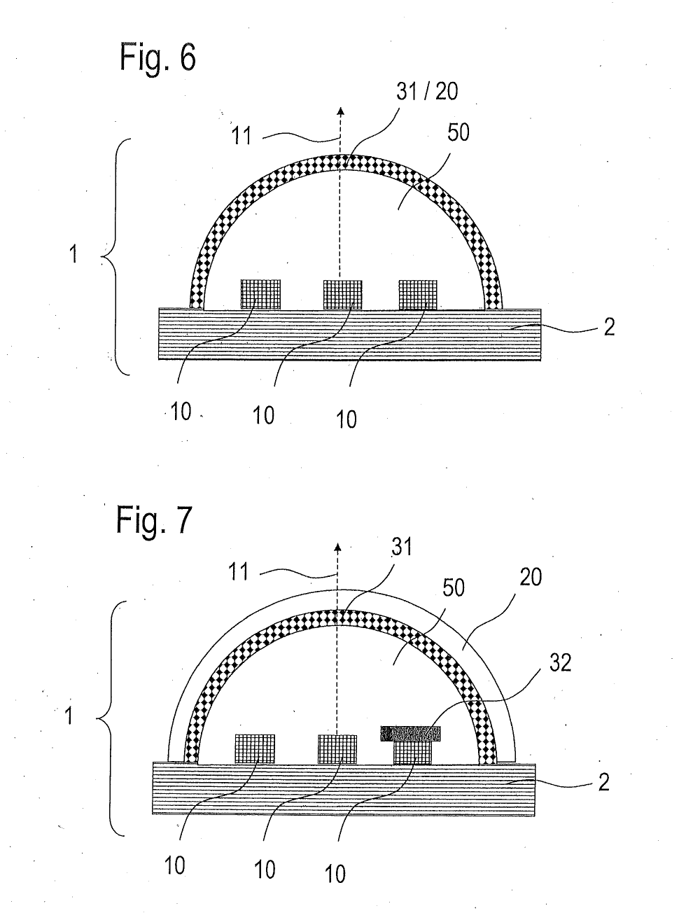

FIG. 5 reproduces a diagram which shows the improved color constancy of our component 100 compared to a conventional component 200. Our component comprises a potting compound consisting of a transparent body 20 and formed into a lens 40, which body consists of poly(dimethylsiloxane) and 50 wt. % of spherical SiO₂ particles and is mixed with 7 wt. % of particles of YAG:Ce. The potting compound of the conventional component consists merely of poly(dimethylsiloxane) and 7 wt. % of particles of YAG:Ce. The Cₓ value is plotted on the y axis, while the angle θ to the main emission direction (θ=0°) is plotted on the x axis. Measure-ments were taken at room temperature directly after start-up of the component. The color point shift in our component 100 is markedly less than that of the conventional component 200.

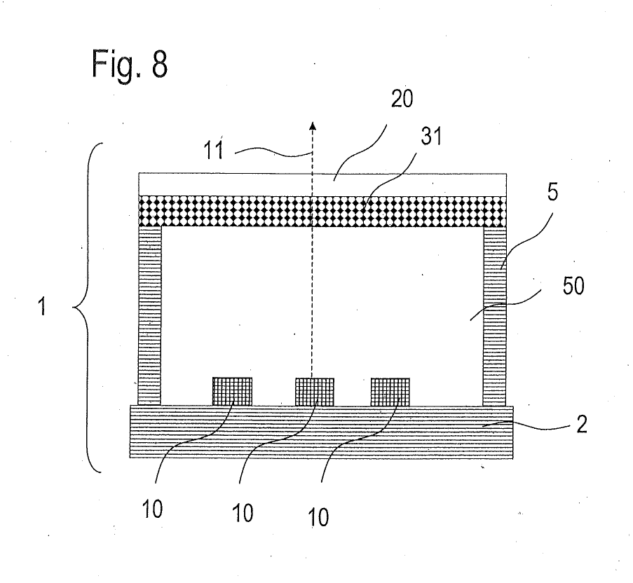

FIG. 6 shows a schematic cross-section through a component 1 with “remote phosphor conversion” according to a further example. One or more radiation sources 10 (three are shown here) are arranged on a carrier 2 comprising a lead frame, and are electrically conductively connected. Bond pads, bonding wire and other electrical connectors are not shown here for the sake of clarity. LED chips may be used as radiation sources 10, these emitting, for example, in the blue or red range of the spectrum.

Downstream of the radiation sources 10, in the beam path 11, a conversion element 31 is arranged which comprises the converter material (not shown separately). In the example shown in FIG. 6, the conversion element also contains an inorganic filler, for example, a metal fluoride or SiO₂ particles and a matrix material adapted thereto as described above, for example, a silicone. Thus, in this example the conversion element also includes a transparent body 20. The converter material may, for example, be finely dispersed in the transparent body such that filler and converter material are at least in part in thermally conductive contact with one another. The conversion element 31 is here formed as a layer with an average layer thickness of, for example, 10 to 1000 μm, in particular of 50 to 500 μm, and takes the form of a curved hollow body. Between the conversion element 31 and the radiation sources is a cavity 50. The cavity 50 may be filled with air or an inert gas, for example, nitrogen or a noble gas. It is also feasible for the cavity 50 to be filled at least in part with a potting compound (not shown here).

In the transparent body 20 the matrix material and the filler are adapted to one another such that the matrix material has a 0.01 to 0.05 higher refractive index and a higher thermo-optic coefficient than the filler such that at operating temperature of the component 1 the difference in the refractive indices is ≦0.015. Thus, at room temperature the transparent body strongly scatters incident light such that the body color of the converter material is barely perceptible to the observer from outside. The radiation-outcoupling region of the component 1 therefore has an aesthetically advantageous matt, white or colorless appearance in the off state. In operation, however, the refractive index difference falls such that the transparent body 20 barely continues to absorb radiation, resulting in high efficiency for the component 1. The transparent body 20 or the conversion element 31 thus acts as a temperature-dependent diffuser.

The filler content in the transparent body amounts to up to 80 wt. %. In this example, a relatively low filler content of 5 to 50 wt. % and as a rule 10 to 40 wt. % is preferably used. In this region a very good scattering action of the transparent body is achieved at room temperature. The filler here has an average grain size of 100 nm to 20 μm. In the example shown in FIG. 6 the average diameter amounts to 1 μm, in particular 200 to 800 nm, which brings about a particularly good scattering action at room temperature or in the off state.

An enveloping layer of glass or a transparent plastics (not shown) may be produced on the conversion element 31, which provides external protection for the component 1 or the conversion element 31.

For example, a radiation source 10 emitting in the blue range of the spectrum, for example, an LED comprising InGaN and a conversion element 31 (remote phosphor conversion) with a mixture of converter materials emitting in the green and red ranges may be used to provide a white-emitting component 1.

It is also possible, for example, to use a combination of a radiation source 10 emitting in the red range, for example, an LED comprising InGaAlP with a radiation source 10 emitting in the blue range, for example, an LED comprising InGaN such that the component 1 contains different radiation sources 10 emitting differently. Conversion with a conversion element 31 (remote phosphor conversion) which, for example, comprises a mixture of converter materials emitting in the green and red ranges may likewise be used here to provide a white-emitting component 1.

FIG. 7 shows a schematic cross-section through a component 1 according to a further example. The elements of this component 1 may correspond to those of the component of FIG. 6. In the component illustrated in FIG. 7, a transparent body 20 is arranged on a conversion element 31 remote from the radiation source. Thus, at least part of the filler in the transparent body 20 is in thermally conductive contact with the converter material of the conversion element 31. The transparent body 20 may have an average layer thickness of 50 to 500 μm.

A further transparent layer of, for example, glass, silicone or plastics, may optionally also be provided between the transparent body 20 and the conversion element 31, the layer likewise producing thermally conductive contact. The conversion element 31 may optionally, as described in FIG. 6, likewise contain a further transparent body.

By way of example, a second conversion element 32 is arranged on a radiation source 10, which second conversion element 32 takes the form, for example, of a converter wafer such that conversion also proceeds close to the radiation source 10 (chip-level conversion). Second conversion elements 32 may also be present for multiple radiation sources 10. One or more second conversion elements may likewise also be present in other examples. For example, in a component 1, a radiation source 10 emitting in the blue range of the spectrum, for example, an LED comprising InGaN, may be combined with a second conversion element 32 containing converter material emitting in the red range (chip-level conversion) and with a mixture of converter materials emitting in the green and red ranges in the conversion element 31 (remote phosphor conversion), to obtain a white-emitting component 1.

FIG. 8 shows a schematic cross-section through a component 1 according to a further example. The radiation sources 10 are arranged in a housing 5 which may be connected to the carrier 2. The internal walls of the housing 5 may be reflective in that they are coated, for exam-ple, with reflective pigments such as TiO₂ or with metal. In the beam path 11 there are arranged a conversion element 31 and, downstream thereof, a transparent body 20. These two elements are shown as flat layers, but they may also be curved. The cavity 50 may also take the form of a recess between housing walls. The housing walls may also be bevelled (not shown here). In the case of the component 1 shown here, for example, the radiation sources 10 and conversion elements 31 mentioned in relation to the previous figures may be used as per the figures.

The components and methods described herein are not restricted by the description given with reference to the examples. Rather, this disclosure encompasses any novel feature and any combination of features, including in particular any combination of features in the appended claims, even if the feature or combination is not itself explicitly indicated in the claims or examples.

1. A radiation-emitting component comprising:
a radiation source containing semiconductor materials which emits first radiation of a first wavelength when in operation;
a transparent body comprising a matrix material and an inorganic filler and arranged at least in part in a beam path of the first radiation;
a converter material arranged at least in part in the beam path of the first radiation and which converts first radiation at least in part into second radiation of a second, longer wavelength;
wherein the converter material is at least in part in thermally conductive contact with at least some of the filler of the transparent body.

2. A component according to claim 1, wherein, at room temperature, the matrix material has a 0.01 to 0.07 higher refractive index and a higher thermo-optic coefficient than the filler such that at operating temperature of the component there is a difference in the refractive indices of ≦0.015.

3. A component according to claim 2, wherein the matrix material has a refractive index which at room temperature is 0.01 to 0.04 higher than the refractive index of the filler.

4. The component according to claim 2, wherein, at operating temperature, the difference in the refractive indices is ≦0.01.

5. A component according to claim 1, wherein the filler comprises at least one metal fluoride.

6. A component according to claim 1, wherein the filler comprises glass, quartz, spherical SiO₂ panicles, a borosilicate glass or a combination thereof.

7. The component according to claim 1, wherein the filler forms continuous filler paths in the transparent body.

8. The component according to claim 1, wherein the transparent body has a thermal conductivity of ≧0.25 W/mK.

9. The component according to claim 1, wherein the transparent body is combined with particles which comprise the converter material.

10. The component according to claim 1, wherein the component comprises a conversion element which comprises the transparent body and the converter material and is remote from the radiation source.

11. The component according to claim 1, wherein the conversion element encloses a curved hollow body.

12. The component according to claim 1, wherein the component comprises a conversion element containing the converter material and remote from the radiation source, and the transparent body is arranged on the side of the conversion element facing away from the radiation source.

13. A method of producing a radiation-emitting component according to claim 1, comprising:
(a) providing a radiation source containing semiconductor materials which emits first radiation of a first wavelength when in operation;
(b) producing a transparent body comprising a matrix material and an inorganic filler;
(c) arranging the transparent body in a beam path of the first radiation; and
(d) arranging converter material in the beam path of the first radiation such that at least some of the converter material is in thermally conductive contact with at least some of the filler of the transparent body.

14. The method according to claim 13, wherein, in method step (b), the matrix material is adapted to the filler such that at room temperature it has a 0.01 to 0.07 higher refractive index and at operating temperature of the component the difference in the refractive indices is ≦0.015.

15. The method according to claim 14, wherein, in method step (b), at least one silicone with organic substituents on the silicon atoms is used as matrix material, and at room temperature the refractive index of the at least one silicone is adjusted from 1.40 to 1.54 by varying the organic substituents and their ratio, these exhibiting different numbers of carbon atoms.

16. A radiation-emitting component comprising:
a radiation source containing semiconductor materials which emits first radiation of a first wavelength when in operation;
a transparent body comprising a matrix material and an inorganic filler and arranged at least in part in a beam path of the first radiation, wherein the inorganic filler has an average grain size of 5 to 20 μm;
a converter material arranged at least in part in the beam path of the first radiation and which converts first radiation at least in part into second radiation of a second, longer wavelength,
wherein the converter material is at least in part in thermally conductive contact with at least some of the filler of the transparent body.
